(19) United States
(12) Patent Application Publication
(10) Pub. No.: US 2021/0342500 A1
(43) Pub. Date: Nov. 4, 2021

(54) SYSTEMS AND METHODS FOR VEHICLE MODELING

(71) Applicant: STEERING SOLUTIONS IP HOLDING CORPORATION, Saginaw, MI (US)

(72) Inventors: Mariam S. George, Lake Orion, MI (US); Michael R. Story, Bay City, MI (US); Farhad Bolourchi, Novi, MI (US); Joachim J. Klesing, Rochester, MI (US); Larry J. Wilson, St. Clair Shores, MI (US); Peter D. Schmitt, Farmington Hills, MI (US)

(21) Appl. No.: 16/865,181

(22) Filed: May 1, 2020

(51) Int. Cl. G06F 30/15; B62D 15/02; G06F 30/20

(52) U.S. Cl. CPC G06F 30/15; G06F 30/20; B62D 15/02

(57) ABSTRACT

A method for vehicle modeling includes receiving one or more design specification characteristics corresponding to a vehicle steering system design and receiving one or more end-of-line characteristics of a vehicle steering system that includes the vehicle steering system design. The method also includes generating a master model of the vehicle steering system design using the one or more design specification characteristics corresponding to the vehicle steering system design and generating at least one initial parameter using the one or more end-of-line characteristics of the vehicle steering system. The method also includes generating a vehicle specific model based on the master model and the at least one initial parameter and receiving operational data corresponding to the vehicle steering system. The method also includes generating at least one subsequent parameter using the operational data and updating the vehicle specific model using the at least one subsequent parameter.

### TECHNICAL FIELD

This disclosure relates to vehicle modeling and in particular to generating and maintaining a digital vehicle model on a cloud-based computing system.

### BACKGROUND OF THE INVENTION

Vehicles, such as cars, trucks, sport utility vehicles, crossovers, mini-vans, or other suitable vehicles, include various components, systems, and features that assist in vehicle operation. For example, such vehicles typically include power steering features, such as an electronic power steering (EPS) system.

The EPS system is typically configured to provide a steering assist to an operator and/or autonomous controller of a corresponding vehicle. For example, the EPS system may be configured to apply an assist torque to an electric motor, which is connected to a steering mechanism. As the operator interacts with a handwheel or steering wheel associated with the steering mechanism, the amount of force or torque applied by the operator on the handwheel or steering wheel is assisted (e.g., reducing amount of force or torque required by the operator to perform a corresponding steering maneuver) by the electric motor.

In addition to power steering features, such vehicles may include additional features such as autonomous driving features, infotainment features, and the like. Typically, these features rely on various sensors, controllers, and/or to assist in operation of the vehicle. Such sensors, controllers, and/or other components may generate data corresponding to the various functions and operations of a vehicle.

### SUMMARY OF THE INVENTION

This disclosure relates generally to vehicle modeling.

An aspect of the disclosed embodiments includes a method for vehicle modeling. The method includes receiving one or more design specification characteristics corresponding to a vehicle steering system design and receiving one or more end-of-line characteristics of a vehicle steering system that includes the vehicle steering system design. The method also includes generating a master model of the vehicle steering system design using the one or more design specification characteristics corresponding to the vehicle steering system design and generating at least one initial parameter using the one or more end-of-line characteristics of the vehicle steering system. The method also includes generating a vehicle specific model based on the master model and the at least one initial parameter and receiving operational data corresponding to the vehicle steering system. The method also includes generating at least one subsequent parameter using the operational data and updating the vehicle specific model using the at least one subsequent parameter.

Another aspect of the disclosed embodiments includes a system for vehicle modeling. The system includes a processor and a memory. The memory includes instructions that, when executed by the processor, cause the processor to: receive one or more design specification characteristics corresponding to a vehicle steering system design; receive one or more end-of-line characteristics of a vehicle steering system that includes the vehicle steering system design; generate a master model of the vehicle steering system design using the one or more design specification characteristics corresponding to the vehicle steering system design; generate at least one initial parameter using the one or more end-of-line characteristics of the vehicle steering system; generate a vehicle specific model based on the master model and the at least one initial parameter; receive operational data corresponding to the vehicle steering system; generate at least one subsequent parameter using the operational data; and update the vehicle specific model using the at least one subsequent parameter.

Another aspect of the disclosed embodiments includes a vehicle modeling system. The system includes a processor and a memory that includes instructions that, when executed by the processor, cause the processor to: receive a master model that includes a digital representation of a class of vehicles corresponding to a vehicle design; receive one or more end-of-line characteristics of a vehicle that includes the vehicle design; generate an initial parameter set using the one or more end-of-line characteristics of the vehicle; generate a vehicle specific physics-based model using the master model and the initial parameter set; generate a vehicle specific machine learning based model using at least one of the vehicle specific physics-based model, the master model, and the initial parameter set; in response to receiving operation data corresponding to the vehicle, update at least one of the vehicle specific physics-based model and the vehicle specific machine learning based model; and selectively determine operational behavior of at least one component of the vehicle using at least one of the vehicle specific physics-based model and the vehicle specific machine learning model.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 generally illustrates a vehicle according to the principles of the present disclosure.

FIGS. 2A and 2B generally illustrate a block diagram of vehicle modeling system according to the principles of the present disclosure.

FIG. 3 generally illustrates a block diagram of a specific vehicle model according to the principles of the present disclosure.

FIG. 4 generally illustrates a physics based portion of a specific vehicle model according to the principles of the present disclosure.

FIG. 5 is a flow diagram generally illustrating a vehicle modeling method according to the principles of the present disclosure.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, vehicles, such as cars, trucks, sport utility vehicles, crossovers, mini-vans, or other suitable vehicles, include various components, systems, and features that assist in vehicle operation. For example, such vehicles typically include power steering features, such as an electronic power steering (EPS) system.

The EPS system is typically configured to provide a steering assist to an operator and/or autonomous controller of a corresponding vehicle. For example, the EPS system may be configured to apply an assist torque to an electric motor, which is connected to a steering mechanism. As the operator interacts with a handwheel or steering wheel associated with the steering mechanism, the amount of force or torque applied by the operator on the handwheel or steering wheel is assisted (e.g., reducing amount of force or torque required by the operator to perform a corresponding steering maneuver) by the electric motor.

In addition to power steering features, such vehicles may include additional features such as autonomous driving features, infotainment features, and the like. Typically, these features rely on various sensors, controllers, and/or to assist in operation of the vehicle. Such sensors, controllers, and/or other components may generate data corresponding to the various functions and operations of a vehicle.

Increasingly, there is a demand analyze such data for accident reconstruction, driver evaluation, preventative maintenance, redundant processing of safety critical controls, haptic assist for the driver, other data driven functions, or a combination thereof. Accordingly, systems and methods, such as those described herein, configured to provide accident reconstruction, driver evaluation, preventative maintenance information, redundant processing of safety critical controls, haptic or other assist for the driver, other data driven functions, or a combination thereof using a comprehensive vehicle model configured to provide driver and vehicle behavior prediction information, system and/or driver reaction information, other data driven information, or a combination thereof may be desirable.

In some embodiments, the systems and methods described herein may be configured to provide a vehicle model (e.g., which may be referred to as a digital twin of a vehicle) that is stored and processed on a remotely located computing device, such as a cloud server or other suitable remotely located computing device. The vehicle model may mirror static properties and/or dynamic behavior of the vehicle and vehicle subsystems.

In some embodiments, the systems and methods described herein may be configured to receive inputs (e.g., steering torque and/or other suitable input) into a vehicle system (e.g., a steering system a chassis system, other vehicle systems, and the like) from a driver of the vehicle and/or sensors configured to sense an environment of the vehicle (e.g., road surface information or other suitable input indicating characteristic of the environment). The systems and methods described herein may be configured to receive outputs (e.g., yaw values, acceleration values, other suitable outputs, or a combination thereof) from the vehicle system and engineering data, production data, warranty data, and usage data (e.g., during operation of the vehicle or other use post-production). The systems and methods described herein may be configured to use the inputs and/or outputs to provide predictions for system faults, maintenance requirements, driver capability information, and driver assist recommendations, accident reconstruction information (e.g., after the occurrence of an accident), vehicle and/or system response to the inputs (e.g., estimated or predicted yaw values, acceleration values, other suitable estimated or predicted outputs, or a combination thereof), other suitable information, or a combination thereof.

In some embodiments, the systems and methods described herein may be configured to provide predictions for system faults, maintenance requirements, driver capability information, and driver assist recommendations, accident reconstruction information (e.g., after the occurrence of an accident), vehicle and/or system response to the inputs (e.g., estimated or predicted yaw values, acceleration values, other suitable estimated or predicted outputs, or a combination thereof), other suitable information, or a combination thereof by predicting system behavior and/or by comparing expected with actual system behavior. The systems and methods described herein may be configured to provide operator state detection (e.g., sleeping or not paying attention), potential failure or fault prediction, maintenance recommendations, navigation directions, object avoidance, and the like.

In some embodiments, the systems and methods described herein may be configured to generate a master vehicle model corresponding to a class of vehicle (e.g., a type of vehicle, a vehicle production model, and the like) associated with the vehicle and/or a class of one or more subsystems of the vehicle (e.g., a vehicle steering system, a vehicle autonomous control system, and the like). The systems and methods described herein may receive data from engineering and design systems (e.g., corresponding to engineering specifications of the vehicle and/or subsystems of the vehicle) and/or end-of-line data (e.g., from systems during manufacturing of the vehicle and/or subsystems of the vehicle). The systems and methods described herein may be configured to generate a master vehicle model representing the class of vehicle and/or the class of the one or more vehicle subsystems.

In some embodiments, the systems and methods described herein may be configured to identify a parameter set (e.g., which may be referred to as a signature) for a specific vehicle. The parameter set may represent every system and/or subsystem in the vehicle. For example, the systems and methods describe herein may receive data from various sensors of the vehicle and may generate a parameter set indicating various measurements, component details, vehicle usage, other suitable information, or a combination there of. The systems and methods described herein may be configured to generate a vehicle specific model using the master vehicle model and the parameter set corresponding to the vehicle. The systems and methods described herein may be configured to generate a plurality of parameter sets corresponding to respective specific vehicles. The systems and methods described herein may be configured to generate a vehicle specific model for each respective specific vehicle using the master model and corresponding ones of the parameter sets.

In some embodiments, the systems and methods described herein may be configured to generate a vehicle specific model that includes one or more constituent models. For example, the vehicle specific model may include a physics-based model and/or a machine learning model to improve predictive accuracy of the vehicle specific model. In some embodiments, the systems and methods described herein may be triggered by a driver input and/or a load onto the vehicle. The systems and methods described herein may be configured to measure vehicle response and compare the measured vehicle response with an anticipated vehicle response via a calculation on a remotely located computing device. The systems and methods described herein may be configured to identify a specific failure model (e.g., tire wear, friction in a steering gear, and the like) using the difference between the predicted and measured vehicle response.

In some embodiments, the systems and methods described herein may be configured to use a vehicle controller (e.g., such as an electronic control unit) to modify trigger points of the vehicle specific model to emulate frequency sweep to generate a fingerprint of a specific failure mode (e.g. for high friction in gear).

In some embodiments, the systems and methods described herein may be configured to enable over-the-air system maintenance via parameter update using the vehicle specific model (e.g., without hardware replacement). For example, the systems and methods described herein may be configured to correct failures (e.g., increased friction in the steering gear or other suitable failures) using an over-the-air updated parameter set. The systems and methods described herein may be configured to generate an update of the signature of the failed system on the remotely located computing device. In some embodiments, the systems and methods described herein may be configured to generate a vehicle specific model comprising at least a power steering model and a lateral vehicle dynamics model.

In some embodiments, the systems and methods described herein may be configured to receive one or more design specification characteristics corresponding to a vehicle steering system design. The systems and methods described herein may be configured to receive one or more end-of-line characteristics of a vehicle steering system that includes the vehicle steering system design. The systems and methods described herein may be configured to generate a master model of the vehicle steering system design using the one or more design specification characteristics corresponding to the vehicle steering system design. In some embodiments, the master model includes a digital representation of a class of vehicle steering systems corresponding to the vehicle steering system design.

In some embodiments, the systems and methods described herein may be configured to generate at least one initial parameter using the one or more end-of-line characteristics of the vehicle steering system. The systems and methods described herein may be configured to generate a vehicle specific model based on the master model and the at least one initial parameter. In some embodiments, the vehicle specific model includes a digital representation of at least the vehicle steering system. In some embodiments, the vehicle specific model includes a first constituent model and a second constituent model. The first constituent model may include a physics-based representation of the vehicle steering system. The second constituent model may include a machine learning based representation of the vehicle steering system. In some embodiments, the master model and the vehicle specific model are stored on a computing device remotely located from the vehicle steering system.

In some embodiments, the systems and methods described herein may be configured to receive operational data corresponding to the vehicle steering system. In some embodiments, the operational data includes at least vehicle sensor data indicating one or more measurements of the vehicle steering system during operation of a vehicle corresponding to the vehicle steering system. The systems and methods described herein may be configured to generate at least one subsequent parameter using the operational data. The systems and methods described herein may be configured to and update the vehicle specific model using the at least one subsequent parameter.

In some embodiments, the systems and methods described herein may be configured to identify a potential fault in the vehicle steering system using the vehicle specific model. In some embodiments, the systems and methods described herein may be configured to identify at least one characteristic of a maneuver previously executed by the vehicle steering system using the vehicle specific model. In some embodiments, the systems and methods described herein may be configured to receive a steering system input and determine, using the vehicle specific model, a future response of the vehicle steering system to the steering system input.

In some embodiments, the systems and methods described herein may be configured to receive a master model that includes a digital representation of a class of vehicles corresponding to a vehicle design. The systems and methods described herein may be configured to receive one or more end-of-line characteristics of a vehicle that includes the vehicle design. The systems and methods described herein may be configured to generate an initial parameter set using the one or more end-of-line characteristics of the vehicle. The systems and methods described herein may be configured to generate a vehicle specific physics-based model using the master model and the initial parameter set. The systems and methods described herein may be configured to generate a vehicle specific machine learning based model using at least one of the vehicle specific physics-based model, the master model, and the initial parameter set. The systems and methods described herein may be configured to, in response to receiving operation data corresponding to the vehicle, update at least one of the vehicle specific physics-based model and the vehicle specific machine learning based model. The systems and methods described herein may be configured to selectively determine operational behavior of at least one component of the vehicle using at least one of the vehicle specific physics-based model and the vehicle specific machine learning model.

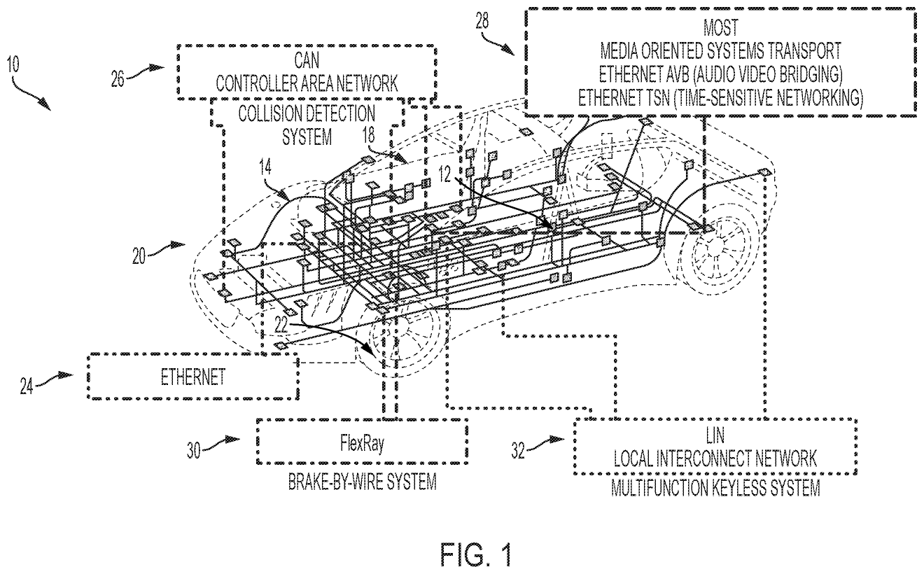

FIG. 1 generally illustrates a vehicle 10 according to the principles of the present disclosure. The vehicle 10 may include any suitable vehicle, such as a car, a truck, a sport utility vehicle, a mini-van, a crossover, any other passenger vehicle, any suitable commercial vehicle, or any other suitable vehicle. While the vehicle 10 is illustrated as a passenger vehicle having wheels and for use on roads, the principles of the present disclosure may apply to other vehicles, such as planes, boats, trains, drones, or other suitable vehicles.

The vehicle 10 includes a vehicle body 12 and a hood 14. A passenger compartment 18 is at least partially defined by the vehicle body 12. Another portion of the vehicle body 12 defines an engine compartment 20. The hood 14 may be moveably attached to a portion of the vehicle body 12, such that the hood 14 provides access to the engine compartment 20 when the hood 14 is in a first or open position and the hood 14 covers the engine compartment 20 when the hood 14 is in a second or closed position. In some embodiments, the engine compartment 20 may be disposed on rearward portion of the vehicle 10 than is generally illustrated.

The passenger compartment 18 may be disposed rearward of the engine compartment 20, but may be disposed forward of the engine compartment 20 in embodiments where the engine compartment 20 is disposed on the rearward portion of the vehicle 10. The vehicle 10 may include any suitable propulsion system including an internal combustion engine, one or more electric motors (e.g., an electric vehicle), one or more fuel cells, a hybrid (e.g., a hybrid vehicle) propulsion system comprising a combination of an internal combustion engine, one or more electric motors, and/or any other suitable propulsion system.

In some embodiments, the vehicle 10 may include a petrol or gasoline fuel engine, such as a spark ignition engine. In some embodiments, the vehicle 10 may include a diesel fuel engine, such as a compression ignition engine. The engine compartment 20 houses and/or encloses at least some components of the propulsion system of the vehicle 10. Additionally, or alternatively, propulsion controls, such as an accelerator actuator (e.g., an accelerator pedal), a brake actuator (e.g., a brake pedal), a steering wheel, and other such components are disposed in the passenger compartment 18 of the vehicle 10. The propulsion controls may be actuated or controlled by a driver of the vehicle 10 and may be directly connected to corresponding components of the propulsion system, such as a throttle, a brake, a vehicle axle, a vehicle transmission, and the like, respectively. In some embodiments, the propulsion controls may communicate signals to a vehicle computer (e.g., drive by wire) which in turn may control the corresponding propulsion component of the propulsion system. As such, in some embodiments, the vehicle 10 may be an autonomous vehicle.

In some embodiments, the vehicle 10 includes a transmission in communication with a crankshaft via a flywheel or clutch or fluid coupling. In some embodiments, the transmission includes a manual transmission. In some embodiments, the transmission includes an automatic transmission. The vehicle 10 may include one or more pistons, in the case of an internal combustion engine or a hybrid vehicle, which cooperatively operate with the crankshaft to generate force, which is translated through the transmission to one or more axles, which turns wheels 22. When the vehicle 10 includes one or more electric motors, a vehicle battery, and/or fuel cell provides energy to the electric motors to turn the wheels 22.

The vehicle 10 may include automatic vehicle propulsion systems, such as a cruise control, an adaptive cruise control, automatic braking control, other automatic vehicle propulsion systems, or a combination thereof. The vehicle 10 may be an autonomous or semi-autonomous vehicle, or other suitable type of vehicle. The vehicle 10 may include additional or fewer features than those generally illustrated and/or disclosed herein.

In some embodiments, the vehicle 10 may include an Ethernet component 24, a controller area network (CAN) bus 26, a media oriented systems transport component (MOST) 28, a FlexRay component 30 (e.g., brake-by-wire system, and the like), and a local interconnect network component (LIN) 32. The vehicle 10 may use the CAN bus 26, the MOST 28, the FlexRay Component 30, the LIN 32, other suitable networks or communication systems, or a combination thereof to communicate various information from, for example, sensors within or external to the vehicle, to, for example, various processors or controllers within or external to the vehicle. The vehicle 10 may include additional or fewer features than those generally illustrated and/or disclosed herein.

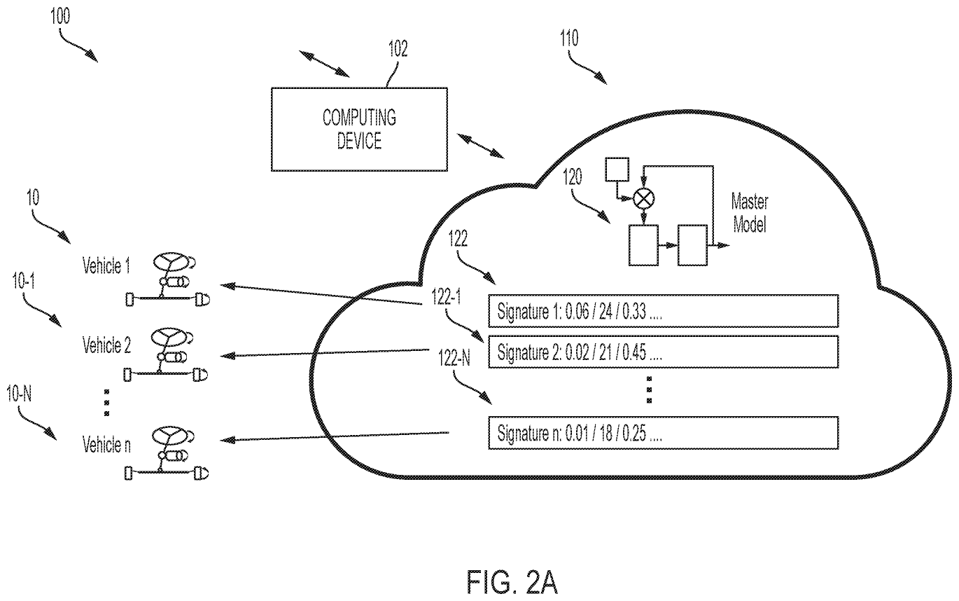

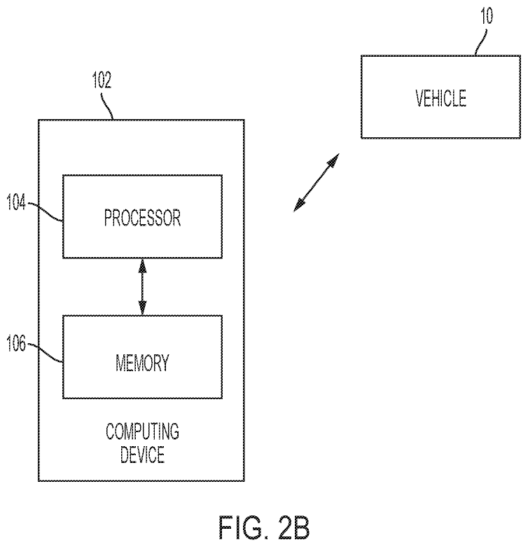

FIGS. 2A and 2B generally illustrate a block diagram of vehicle modeling system 100 according to the principles of the present disclosure. The system 100 may include a computing device 102 and a remotely located computing system 110. In some embodiments, the system 100 may include two or more computing devices and may communicate with two or more remotely located computing systems. The remotely located computing system 110 may include any suitable remotely located computing system, such as a cloud computing system comprising one or more servers disposed in respective datacenters, or any suitable remotely located computing system.

The computing device 102 may include any suitable computing device including a desktop computer, a laptop computing, a mobile computing device, or any suitable computing device. In some embodiments, the computing device 102 may communicate with the remotely located computing system. For example, the computing device 102 may be disposed remotely from the remotely located computing system 110 and may store, at least, one or more vehicle models configured to represent one or more respective vehicles. Additionally, or alternatively, the computing device 102 may be disposed proximately or within the remotely located computing system 110.

The computing device 102 may include a processor 104 and a memory 106, as is generally illustrated in FIG. 2B. The processor 104 may include any suitable processor, such as those described herein. Additionally, or alternatively, the computing device 102 may include any suitable number of processors, in addition to or other than the processor 104. The memory 106 may comprise a single disk or a plurality of disks (e.g., hard drives), and includes a storage management module that manages one or more partitions within the memory 106. In some embodiments, memory 106 may include flash memory, semiconductor (solid state) memory or the like. The memory 106 may include Random Access Memory (RAM), a Read-Only Memory (ROM), or a combination thereof. The memory 106 may include instructions that, when executed by the processor 104, cause the processor 104 to, at least, perform the functions associated with the systems and methods described herein.

In some embodiments, the computing device 102 may be configured to provide predictions for system faults, maintenance requirements, driver capability information, and driver assist recommendations, accident reconstruction information (e.g., after the occurrence of an accident), vehicle and/or system response to the inputs (e.g., estimated or predicted yaw values, acceleration values, other suitable estimated or predicted outputs, or a combination thereof), other suitable information, or a combination thereof.

The computing device 102 may receive one or more design specification characteristics corresponding to a vehicle steering system design and/or other systems of subsystems of a class of vehicle corresponding to the vehicle 10. For example, the computing device 102 may receive input indicating engineering and/or design information corresponding to engineering and/or design specifications of a class of vehicle corresponding to the vehicle 10 and/or other vehicles 10-1 to 10-N. The vehicles 10-1 to 10-N may include features similar to or different from the vehicle 10. The engineering and/or design information may include engineering tolerances, component model number or specification, component dimensions (e.g., weight, length, width, depth, and the like), component features (e.g., functions that various components are capable of performing), sensor location, controller type, any other suitable engineering and design specification, or a combination thereof of vehicle steering system design and/or other systems or subsystems of the vehicle 10. Additionally, or alternatively, the one or more design specification characteristics may include warranty information, sales information, safety feature information, recall information, other suitable information, or a combination thereof of the class of vehicle steering system and/or the systems or subsystems corresponding to the class of vehicle. It should be understood that the vehicle 10 and the vehicles 10-1 to 10-N may belong to or be associated with the same or different classes of vehicle and may include the same or different classes of vehicle steering systems.

In some embodiments, the computing device 102 may receive one or more end-of-line characteristics of a vehicle steering system that includes the vehicle steering system design and/or other subsystems or systems of the vehicle 10. The end-of-line characteristics may include actual manufacturing components used during production of the vehicle steering system, the class of vehicle steering system, the vehicle 10, and/or the class of vehicle corresponding to the vehicle 10. Additionally, or alternatively, the end-of-line characteristics may include production measurements, production tolerances, other suitable production information, or a combination thereof of the vehicle steering system, the class of vehicle steering system, the vehicle 10, and/or the class of vehicle corresponding to the vehicle 10.

In some embodiments, the computing device 102 may generate a master vehicle model of the vehicle steering system design, the class of vehicle associated with the vehicle 10, and/or the class or classes of vehicle corresponding to the vehicles 10-1 to 10-N using the one or more design specification characteristics. Additionally, or alternatively, the computing device 102 may generate a master vehicle model of the vehicle steering system design, the class of vehicle associated with the vehicle 10, and/or the class or classes of vehicle corresponding to the vehicles 10-1 to 10-N using the one or more design specification characteristics and the one or more end-of-line characteristics. For example, the computing device 102 may generate a master vehicle model 120 corresponding the vehicle steering system design (e.g., the class of vehicle steering systems corresponding to the vehicle steering system of the vehicle 10 and/or the vehicles 10-1 to 10-N). In some embodiments, the computing device 102 may retrieve or receive the master vehicle model from another computing device, the vehicle 10 and/or the vehicles 10-1 to 10-N, any other suitable location, or a combination thereof.

The master vehicle model 120 may include a digital representation of the vehicle steering system design, the class of vehicle associated with the vehicle 10, and/or the class or classes of vehicle corresponding to the vehicles 10-1 to 10-N. The computing device 102 may store the master vehicle model 120 on the remotely located computing system 110. Additionally, or alternatively, the computing device 102 may store the master vehicle model 120 on a memory of the corresponding vehicle 10 or vehicles 10-1 to 10-N.

In some embodiments, the computing device 102 may generate at least one initial parameter or parameter set (e.g., a signature) using the one or more end-of-line characteristics of the vehicle steering system, the vehicle 10, and/or the vehicles 10-1 to 10-N. For example, the computing device 102 may generate a parameter set 122 corresponding to the vehicle steering system of the vehicle 10. The computing device 102 may generate one or more parameter sets 122-1 to 122-N corresponding to the vehicles 10-1 to 10-N, respectively. The parameter set 122 may include a value, such as a numeric string, or other suitable value. The parameter set 122 may represent system or component information specific to the vehicle steering system of the vehicle 10. It should be understood that the computing device 102 may generate parameter sets corresponding to the vehicle 10 and/or to other components, systems, or subsystems of the vehicle 10.

In some embodiments, the computing device 102 may receive operational data corresponding to the vehicle steering system, the vehicle 10, and/or the vehicles 10-1 to 10-N. The operational data may include vehicle sensor data indicating one or more measurements of the vehicle steering system, the vehicle 10, and/or the vehicles 10-1 to 10-N during operation. For example, the operation data may include sensor data indicating handwheel friction of a handwheel of the vehicle steering system, wheel angle corresponding to an applied handwheel torque, other suitable measurements of the vehicle steering system, or a combination thereof. It should be understood that the computing device 102 may receive any suitable operation data corresponding to any system or subsystem of the vehicle 10 and/or the vehicles 10-1 to 10-N.

In some embodiments, the computing device 102 may generate at least one subsequent parameter based on the operational data. For example, the computing device 102 may generate a parameter or a parameter set indicating the measurements and/or other information corresponding to the operational data. The computing device 102 may update the parameter set 122 using the at least one subsequent parameter or parameter set. In some embodiments, the computing device 102 may continuously or periodically receive operational data and may continuously or periodically update the parameter set 122 based on the operational data. It should be understood that the computing device 102 may update the parameter sets 122-1 to 122-N based on receiving corresponding operational data.

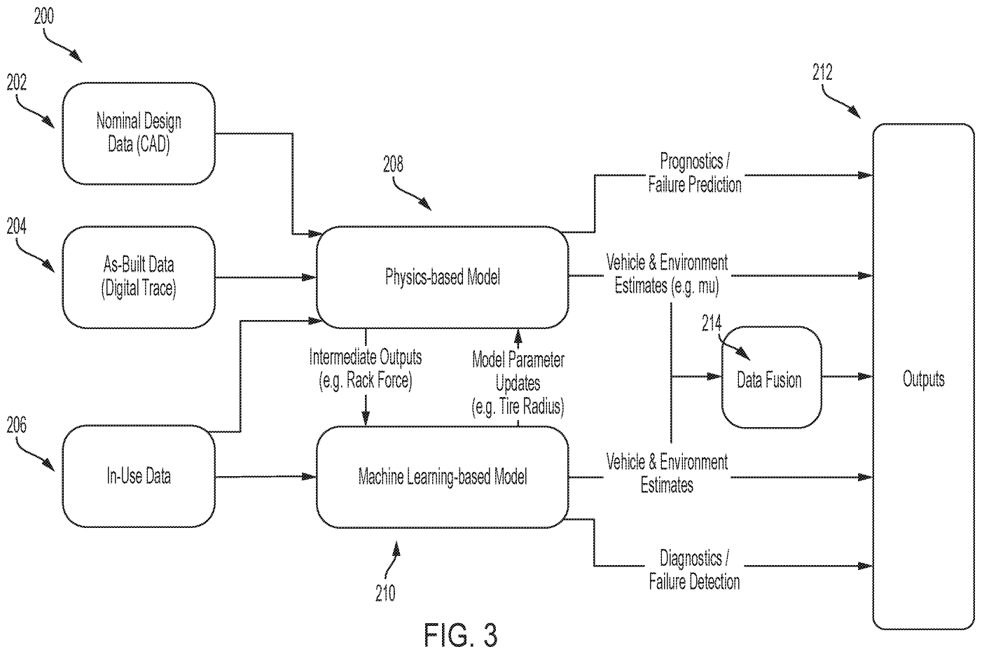

In some embodiments, the computing device 102 may generate a vehicle specific model, such as the vehicle specific model 200 as is generally illustrated in FIG. 3, based on the master vehicle model 120 and the parameter set 122. The vehicle specific model 200 may include nominal design data (e.g., computer aided design data) 202, as-built data (e.g., digital trace data) 204, and in-use data 206. The nominal design data 202 may correspond to the one or more design specification characteristics. The as-build data may correspond to the one or more end-of-line characteristics. The in-use data 206 may correspond to the operational data. In some embodiments, the computing device 102 may retrieve or receive the vehicle specific model from another computing device, the vehicle 10 and/or the vehicles 10-1 to 10-N, any other suitable location, or a combination thereof.

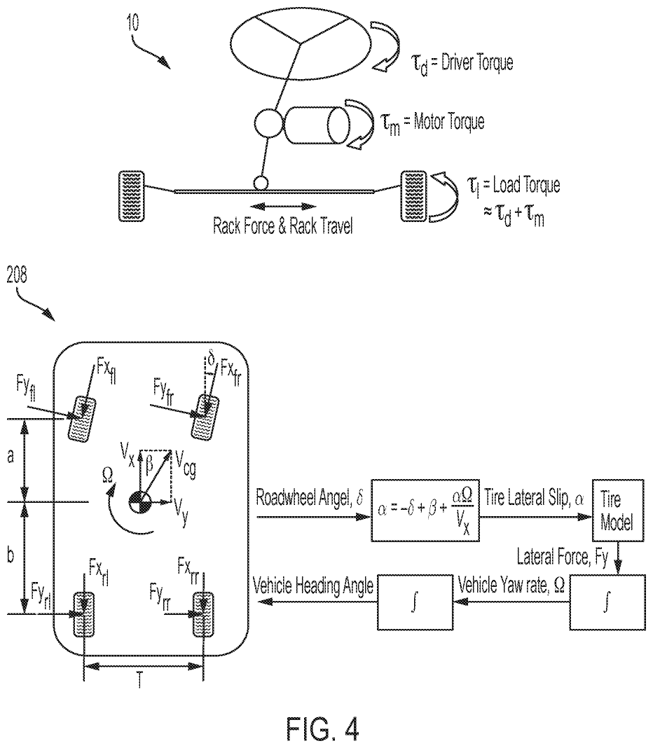

The vehicle specific model may include a first constituent model 208. The first constituent model 208 may include a physics-based model, as is generally illustrated in FIG. 4. The first constituent model 208 may receive the nominal design data 202, the as-build data 204, the in-use data 206, any other suitable data, or a combination thereof. The computing device 102 may generate the first constituent model 208 using the nominal design data 202, the as-build data 204, the in-use data 206, any other suitable data, or a combination thereof. The first constituent model 208 may represent physical aspects of the vehicle steering system (e.g., and/or the vehicle 10 and the vehicles 10-1 to 10-N). For example, the first constituent model 208 may represent roadwheel angle, tire lateral slip, vehicle heading angle, vehicle yaw rate, other suitable physical aspects of the vehicle steering system (e.g., and/or the vehicle 10 and the vehicles 10-1 to 10-N), or a combination thereof.

In some embodiments, the vehicle specific model 200 includes a second constituent model 210. It should be understood that the vehicle specific model 200 may include only the first constituent model 208, only the second constituent model 210, both of the first constituent model 208 and the second constituent model 210, additional constituent models, or any combination of the first constituent model 208, the second constituent model 210, and any additional suitable constituent models. The second constituent model 210 may include a machine learning-based model. The second constituent model 210 may be trained using any suitable data corresponding to the vehicle steering system design, the class of vehicle corresponding to the vehicles 10, 10-1 and 10-N, the vehicle steering system, the vehicles 10, the vehicles 10-1 to 10-N, any other suitable data, or a combination thereof. The second constituent model 210 may receive the in-use data 206 and/or any other suitable data.

In some embodiments, the first constituent model 208 and/or the second constituent model 210 receive inputs (e.g., steering torque and/or other suitable input) corresponding to the vehicle steering system and/or any suitable system or subsystem of the vehicle 10 (e.g., a steering system a chassis system, other vehicle systems, and the like). The inputs may be generated by a driver of the vehicle 10 and/or sensors configured to sense an environment of the vehicle 10 (e.g., road surface information or other suitable input indicating characteristic of the environment).

In some embodiments, the first constituent model 208 and/or the second constituent model 210 receive outputs (e.g., yaw values, acceleration values, other suitable outputs, or a combination thereof) from the sensors of the vehicle 10. The first constituent model 208 may determine one or more intermediate outputs (e.g., such as a rack force or other suitable output). The first constituent model 208 may communicate the one or more intermediate outputs to the second constituent model 210. The second constituent model 210 may analyze the one or more intermediate outputs and/or the in-use data 206 and may generate one or more predicted parameters (e.g., a current tire radius) or responses of the vehicle steering system (e.g., or the vehicle 10 and/or the vehicles 10-1 to 10-N). The second constituent model 210 may update the parameter set 122 based on the predicted parameters or responses. The second constituent model 210 may communicate the update parameter set 122 to the first constituent model 208.

In some embodiments, the computing device 102 may use the inputs and/or outputs to and from the first constituent model 208 and/or the second constituent model 210 to provide outputs 212. The outputs 212 may include predictions for system faults, maintenance requirements, driver capability information, and driver assist recommendations, accident reconstruction information (e.g., after the occurrence of an accident), vehicle and/or system response to the inputs (e.g., estimated or predicted yaw values, acceleration values, other suitable estimated or predicted outputs or a combination thereof), vehicle and environment estimates (e.g., mu from the first constituent model 208), vehicle and environment estimates from the second constituent model 210, diagnosis or failure detection, other suitable information, or a combination thereof. The vehicle specific model 200 may include a data fusion module 214. The data fusion module 214 may be configured to perform data fusion on the vehicle and environment estimates from the first constituent model 208 with the vehicle and environment estimates from the second constituent model 210, The data fusion module 214 may be configured to perform data fusion on any other suitable output of the first constituent model 208 and the second constituent model 210.

In some embodiments, the computing device 102 may identify a potential fault in the vehicle steering system using the inputs and/or outputs to and/or from the first constituent model 208 and the second constituent model 210. In some embodiments, the computing device 102 may identify at least one characteristic of a maneuver previously executed by the vehicle steering system using the inputs and/or outputs to and/or from the first constituent model 208 and the second constituent model 210. In some embodiments, the computing device 102 may receive a steering system input and determine, using the inputs and/or outputs to and/or from the first constituent model 208 and the second constituent model 210, a future response of the vehicle steering system to the steering system input. It should be understood that the computing device 102 may generate any suitable output including any suitable prediction, estimate, accident recreation information, drive state or response information, any other suitable output or information, or a combination thereof.

In some embodiments, the system 100 and/or the computing device 102 may perform the methods described herein. However, the methods described herein as performed by the system 100 and/or the computing device 102 are not meant to be limiting, and any type of software executed on a controller can perform the methods described herein without departing from the scope of this disclosure. For example, a controller, such as a processor executing software within a computing device, can perform the methods described herein.

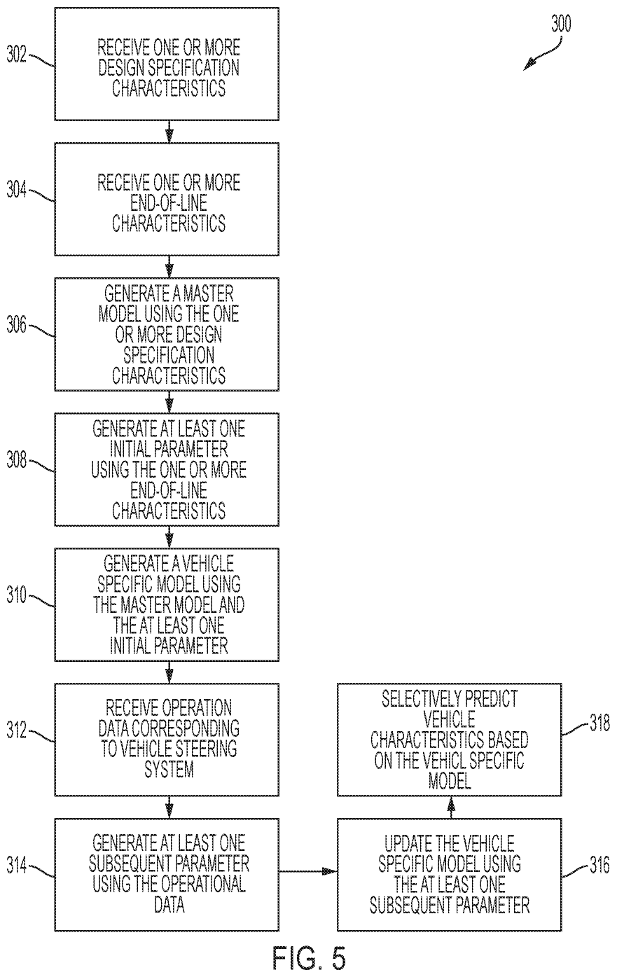

FIG. 5 is a flow diagram generally illustrating a vehicle modeling method 300 according to the principles of the present disclosure. At 302, the method 300 receives one or more design specification characteristics corresponding to a vehicle steering system design. For example, the computing device 102 receives the one or more design specification characteristics corresponding to the vehicle steering system design.

At 304, the method 300 receives one or more end-of-line characteristics of a vehicle steering system that includes the vehicle steering system design. For example, the computing device 102 receives the one or more end-of-line characteristics of the vehicle steering system corresponding to the vehicle steering system design.

At 306, the method 300 generates a master model of the vehicle steering system design using the one or more design specification characteristics. For example, the computing device 102 generates the master vehicle model 120 of the vehicle steering system design using the one or more design specification characteristics and/or the one or more end-of-line characteristics

At 308, the method 300 generates at least one initial parameter using the one or more end-of-line characteristics. For example, the computing device 102 generates the at least one initial parameter using the one or more end-of-line characteristics. The computing device 102 may generate the parameter set 122 using the at least one initial parameter.

At 310, the method 300 generates a vehicle specific model based on the master model and the at least one initial parameter. For example, the computing device 102 generates the vehicle specific model 200 based on the master vehicle model 120 and the parameter set 122.

At 312, the method 300 receives operational data corresponding to the vehicle steering system. For example, the computing device 102 receives operational data (e.g., the in-use data 206) corresponding to the vehicle steering system.

At 314, the method 300 generates at least one subsequent parameter using the operational data. For example, the computing device 102 generate the at least one subsequent parameter using the operation data (e.g., the in-use data 206). The computing device 102 may update the parameter set 122 using the at least one subsequent parameter.

At 316, the method 300 updates the vehicle specific model using the at least one subsequent parameter. For example, the computing device 102 updates the vehicle specific model 200 using the updated parameter set 122.

At 318, the method 300 selectively predict vehicle characteristics based on the vehicle specific model. For example, the computing device 102 may selectively predict system faults, maintenance requirements, driver capability information, and driver assist recommendations, accident reconstruction information (e.g., after the occurrence of an accident), vehicle and/or system response (e.g., estimated or predicted yaw values, acceleration values, other suitable estimated or predicted outputs or a combination thereof), other suitable vehicle characteristic predictions, or a combination thereof using the vehicle specific model 200.

In some embodiments, a method for vehicle modeling includes receiving one or more design specification characteristics corresponding to a vehicle steering system design and receiving one or more end-of-line characteristics of a vehicle steering system that includes the vehicle steering system design. The method also includes generating a master model of the vehicle steering system design using the one or more design specification characteristics corresponding to the vehicle steering system design and generating at least one initial parameter using the one or more end-of-line characteristics of the vehicle steering system. The method also includes generating a vehicle specific model based on the master model and the at least one initial parameter and receiving operational data corresponding to the vehicle steering system. The method also includes generating at least one subsequent parameter using the operational data and updating the vehicle specific model using the at least one subsequent parameter.

In some embodiments, the operational data includes at least vehicle sensor data indicating one or more measurements of the vehicle steering system during operation of a vehicle corresponding to the vehicle steering system. In some embodiments, the master model includes a digital representation of a class of vehicle steering systems corresponding to the vehicle steering system design. In some embodiments, the vehicle specific model includes a digital representation of at least the vehicle steering system. In some embodiments, the vehicle specific model includes a first constituent model and a second constituent model, wherein the first constituent model includes a physics-based representation of the vehicle steering system, and wherein the second constituent model includes a machine learning based representation of the vehicle steering system.

In some embodiments, the method also includes identifying, using at least one of the first constituent model and the second constituent model, a potential fault in the vehicle steering system. In some embodiments, the method also generating, using at least the first constituent model, accident reconstruction information. In some embodiments, the method also receiving a steering system input and predicting, using at least the second constituent model, a future response of the vehicle steering system to the steering system input.

In some embodiments, the method also includes identifying a potential fault in the vehicle steering system using the vehicle specific model. In some embodiments, the method also includes identifying at least one characteristic of a maneuver previously executed by the vehicle steering system using the vehicle specific model. In some embodiments, the master model and the vehicle specific model are stored on a computing device remotely located from the vehicle steering system. In some embodiments, the method also includes receiving a steering system input and determining, using the vehicle specific model, a future response of the vehicle steering system to the steering system input.

In some embodiments, a system for vehicle modeling includes a processor and a memory. The memory includes instructions that, when executed by the processor, cause the processor to: receive one or more design specification characteristics corresponding to a vehicle steering system design; receive one or more end-of-line characteristics of a vehicle steering system that includes the vehicle steering system design; generate a master model of the vehicle steering system design using the one or more design specification characteristics corresponding to the vehicle steering system design; generate at least one initial parameter using the one or more end-of-line characteristics of the vehicle steering system; generate a vehicle specific model based on the master model and the at least one initial parameter; receive operational data corresponding to the vehicle steering system; generate at least one subsequent parameter using the operational data; and update the vehicle specific model using the at least one subsequent parameter.

In some embodiments, the operational data includes at least vehicle sensor data indicating one or more measurements of the vehicle steering system during operation of a vehicle corresponding to the vehicle steering system. In some embodiments, the master model includes a digital representation of a class of vehicle steering systems corresponding to the vehicle steering system design. In some embodiments, the vehicle specific model includes a digital representation of at least the vehicle steering system. In some embodiments, the vehicle specific model includes a first constituent model and a second constituent model, wherein the first constituent model includes a physics-based representation of the vehicle steering system, and wherein the second constituent model includes a machine learning based representation of the vehicle steering system. In some embodiments, the instructions further cause the processor to identify a potential fault in the vehicle steering system using the vehicle specific model. In some embodiments, the instructions further cause the processor to identify at least one characteristic of a maneuver previously executed by the vehicle steering system using the vehicle specific model. In some embodiments, the master model and the vehicle specific model are stored on a computing device remotely located from the vehicle steering system. In some embodiments, the instructions further cause the processor to receive a steering system input and determine, using the vehicle specific model, a future response of the vehicle steering system to the steering system input.

In some embodiments, a vehicle modeling system a processor and a memory that includes instructions that, when executed by the processor, cause the processor to: receive a master model that includes a digital representation of a class of vehicles corresponding to a vehicle design; receive one or more end-of-line characteristics of a vehicle that includes the vehicle design; generate an initial parameter set using the one or more end-of-line characteristics of the vehicle; generate a vehicle specific physics-based model using the master model and the initial parameter set; generate a vehicle specific machine learning based model using at least one of the vehicle specific physics-based model, the master model, and the initial parameter set; in response to receiving operation data corresponding to the vehicle, update at least one of the vehicle specific physics-based model and the vehicle specific machine learning based model; and selectively determine operational behavior of at least one component of the vehicle using at least one of the vehicle specific physics-based model and the vehicle specific machine learning model.

In some embodiments, the at least one component of the vehicle includes a vehicle steering system.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

Implementations the systems, algorithms, methods, instructions, etc., described herein can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

As used herein, the term module can include a packaged functional hardware unit designed for use with other components, a set of instructions executable by a controller (e.g., a processor executing software or firmware), processing circuitry configured to perform a particular function, and a self-contained hardware or software component that interfaces with a larger system. For example, a module can include an application specific integrated circuit (ASIC), a Field Programmable Gate Array (FPGA), a circuit, digital logic circuit, an analog circuit, a combination of discrete circuits, gates, and other types of hardware or combination thereof. In other embodiments, a module can include memory that stores instructions executable by a controller to implement a feature of the module.

Further, in one aspect, for example, systems described herein can be implemented using a general-purpose computer or general-purpose processor with a computer program that, when executed, carries out any of the respective methods, algorithms, and/or instructions described herein. In addition, or alternatively, for example, a special purpose computer/processor can be utilized which can contain other hardware for carrying out any of the methods, algorithms, or instructions described herein.

Further, all or a portion of implementations of the present disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or a semiconductor device. Other suitable mediums are also available.

The above-described embodiments, implementations, and aspects have been described in order to allow easy understanding of the present invention and do not limit the present invention. On the contrary, the invention is intended to cover various modifications and equivalent arrangements included within the scope of the appended claims, which scope is to be accorded the broadest interpretation to encompass all such modifications and equivalent structure as is permitted under the law.

Having thus described the invention, it is claimed:

1. A method for vehicle modeling; the method comprising:
receiving one or more design specification characteristics corresponding to a vehicle steering system design;
receiving one or more end-of-line characteristics of a vehicle steering system that includes the vehicle steering system design;
generating a master model of the vehicle steering system design using the one or more design specification characteristics corresponding to the vehicle steering system design;
generating at least one initial parameter using the one or more end-of-line characteristics of the vehicle steering system;
generating a vehicle specific model based on the master model and the at least one initial parameter;
receiving operational data corresponding to the vehicle steering system;
generating at least one subsequent parameter using the operational data; and
updating the vehicle specific model using the at least one subsequent parameter.

2. The method of claim 1, wherein the operational data includes at least vehicle sensor data indicating one or more measurements of the vehicle steering system during operation of a vehicle corresponding to the vehicle steering system.

3. The method of claim 1, wherein the master model includes a digital representation of a class of vehicle steering systems corresponding to the vehicle steering system design.

4. The method of claim 1, wherein the vehicle specific model includes a digital representation of at least the vehicle steering system.

5. The method of claim 1, wherein the vehicle specific model includes a first constituent model and a second constituent model, wherein the first constituent model includes a physics-based representation of the vehicle steering system, and wherein the second constituent model includes a machine learning based representation of the vehicle steering system.

6. The method of claim 5, further comprising identifying, using at least one of the first constituent model and the second constituent model, a potential fault in the vehicle steering system.

7. The method of claim 5, further comprising generating, using at least the first constituent model, accident reconstruction information.

8. The method of claim 5, further comprising:
receiving a steering system input; and
predicting, using at least the second constituent model, a future response of the vehicle steering system to the steering system input.

9. The method of claim 1, wherein the master model and the vehicle specific model are stored on a computing device remotely located from the vehicle steering system.

10. A system for vehicle modeling; the system comprising:
a processor; and
a memory including instructions that, when executed by the processor, cause the processor to:
receive one or more design specification characteristics corresponding to a vehicle steering system design;
receive one or more end-of-line characteristics of a vehicle steering system that includes the vehicle steering system design;
generate a master model of the vehicle steering system design using the one or more design specification characteristics corresponding to the vehicle steering system design;
generate at least one initial parameter using the one or more end-of-line characteristics of the vehicle steering system; and
generate a vehicle specific model based on the master model and the at least one initial parameter;
receive operational data corresponding to the vehicle steering system;
generate at least one subsequent parameter using the operational data; and
update the vehicle specific model using the at least one subsequent parameter.

11. The system of claim 10, wherein the operational data includes at least vehicle sensor data indicating one or more measurements of the vehicle steering system during operation of a vehicle corresponding to the vehicle steering system.

12. The system of claim 10, wherein the master model includes a digital representation of a class of vehicle steering systems corresponding to the vehicle steering system design.

13. The system of claim 10, wherein the vehicle specific model includes a digital representation of at least the vehicle steering system.

14. The system of claim 10, wherein the vehicle specific model includes a first constituent model and a second constituent model, wherein the first constituent model includes a physics-based representation of the vehicle steering system, and wherein the second constituent model includes a machine learning based representation of the vehicle steering system.

15. The system of claim 10, wherein the instructions further cause the processor to identify a potential fault in the vehicle steering system using the vehicle specific model.

16. The system of claim 10, wherein the instructions further cause the processor to identify at least one characteristic of a maneuver previously executed by the vehicle steering system using the vehicle specific model.

17. The system of claim 10, wherein the master model and the vehicle specific model are stored on a computing device remotely located from the vehicle steering system.

18. The system of claim 10, wherein the instructions further cause the processor to:
receive a steering system input; and
determine, using the vehicle specific model, a future response of the vehicle steering system to the steering system input.

19. A vehicle modeling system, comprising:
a processor; and
a memory that includes instructions that, when executed by the processor, cause the processor to:
receive a master model that includes a digital representation of a class of vehicles corresponding to a vehicle design;
receive one or more end-of-line characteristics of a vehicle that includes the vehicle design;
generate an initial parameter set using the one or more end-of-line characteristics of the vehicle;
generate a vehicle specific physics-based model using the master model and the initial parameter set;
generate a vehicle specific machine learning based model using at least one of the vehicle specific physics-based model, the master model, and the initial parameter set;
in response to receiving operation data corresponding to the vehicle, update at least one of the vehicle specific physics-based model and the vehicle specific machine learning based model; and
selectively determine operational behavior of at least one component of the vehicle using at least one of the vehicle specific physics-based model and the vehicle specific machine learning model.

20. The system of claim 19, wherein the at least one component of the vehicle includes a vehicle steering system.
